(19) United States
(12) Patent Application Publication
(10) Pub. No.: US 2024/0071836 A1
(43) Pub. Date: Feb. 29, 2024

(54) BACKSIDE CONTACTS FOR CELL HEIGHT SCALING

(71) Applicant: INTERNATIONAL BUSINESS MACHINES CORPORATION, Armonk, NY (US)

(72) Inventors: Ruilong Xie, Niskayuna, NY (US); Chanro Park, Clifton Park, NY (US); Kangguo Cheng, Schenectady, NY (US); Julien Frougier, Albany, NY (US); Lawrence A. Clevenger, Saratoga Springs, NY (US)

(21) Appl. No.: 17/899,111

(22) Filed: Aug. 30, 2022

(51) Int. Cl. H01L 21/8238; H01L 27/092; H01L 29/40; H01L 29/417; H01L 29/423; H01L 29/66; H01L 29/775

(52) U.S. Cl. CPC H01L 21/823871; H01L 21/823814; H01L 21/823878; H01L 27/092; H01L 29/401; H01L 29/41733; H01L 29/41775; H01L 29/42392; H01L 29/66439; H01L 29/775; H01L 29/78696

(57) ABSTRACT

A semiconductor structure is presented including a first dielectric isolation pillar disposed between a pair of p-type field effect transistors (pFETs), a second dielectric isolation pillar disposed between a pair of n-type FETs (nFETs), a first source/drain (S/D) epi region having a first contact electrically connected to a backside power delivery network (BSPDN), the first contact being disposed on one side of the first dielectric isolation pillar, and a second S/D epi region having a second contact electrically connected to back-end-of-line (BEOL) components, the second contact being disposed on the other side of the first dielectric isolation pillar.

### BACKGROUND

The present invention relates generally to semiconductor devices, and more specifically, to constructing backside contacts for cell height scaling.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a first dielectric isolation pillar disposed between a pair of p-type field effect transistors (pFETs), a second dielectric isolation pillar disposed between a pair of n-type FETs (nFETs), a first source/drain (S/D) epi region having a first contact electrically connected to a backside power delivery network (BSPDN), the first contact being disposed on one side of the first dielectric isolation pillar, and a second S/D epi region having a second contact electrically connected to back-end-of-line (BEOL) components, the second contact being disposed on the other side of the first dielectric isolation pillar.

In accordance with another embodiment, a semiconductor structure is provided. The semiconductor structure includes at least one dielectric isolation pillar disposed between a pair of field effect transistors (FETs), a first source/drain (S/D) epi region having a first contact electrically connected to a backside power delivery network (BSPDN), the first contact being disposed along a first sidewall of the at least one dielectric isolation pillar, and a second S/D epi region having a second contact electrically connected to back-end-of-line (BEOL) components, the second contact being disposed along a second sidewall of the at least one dielectric isolation pillar, wherein the first sidewall is in opposed relation to the second sidewall.

In accordance with yet another embodiment, a method for forming a semiconductor structure is provided. The method includes constructing a first dielectric isolation pillar between a pair of p-type field effect transistors (pFETs), constructing a second dielectric isolation pillar between a pair of n-type FETs (nFETs), forming a first source/drain (S/D) epi region having a first contact and electrically connected to a backside power delivery network (BSPDN), the first contact being disposed on one side of the first dielectric isolation pillar, and forming a second S/D epi region having a second contact and electrically connected to back-end-of-line (BEOL) components, the second contact being disposed on the other side of the first dielectric isolation pillar.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a nanosheet stack formed over a substrate, where first and second hardmasks, and a dielectric liner are also formed over the nanosheet stack, in accordance with an embodiment of the present invention;

FIG. 2 is a cross-sectional view of the semiconductor structure of FIG. 1 where nanosheet stack patterning takes place, in accordance with an embodiment of the present invention;

FIG. 3 is a cross-sectional view of the semiconductor structure of FIG. 2 where the second hardmask and remaining dielectric liner portions are selectively removed thus exposing the first hardmask, in accordance with an embodiment of the present invention;

FIG. 4 is a cross-sectional view of the semiconductor structure of FIG. 3 where a first conformal dielectric layer is deposited to pinch-off NFET-to-NFET spacing and PFET-to-PFET spacing, in accordance with an embodiment of the present invention;

FIG. 5 is a cross-sectional view of the semiconductor structure of FIG. 4 where an isotropic etch back is performed such that conformal dielectric pillars are present between the NFET devices and between the PFET devices, in accordance with an embodiment of the present invention;

FIG. 6 is a cross-sectional view of the semiconductor structure of FIG. 5 where shallow trench isolation (STI) regions are formed and the first hardmask is selectively removed to expose a top portion of the conformal dielectric pillars, in accordance with an embodiment of the present invention;

FIG. 7 is a cross-sectional view of the semiconductor structure of FIG. 6 where a silicon germanium (SiGe) layer with a high concentration of germanium (Ge) is removed and replaced with a bottom dielectric isolation (BDI) layer, and where the sacrificial layers of the nanosheet stack are removed and replaced with a high-k metal gate (HKMG), in accordance with an embodiment of the present invention;

FIG. 8 is a cross-sectional view of the semiconductor structure of FIG. 7 where a hardmask is deposited for gate cut patterning and inner spacers are formed to decrease the critical dimension (CD), in accordance with an embodiment of the present invention;

FIG. 9 is a cross-sectional view of the semiconductor structure of FIG. 8 where a gate cut takes place, the gate cut is filled with a dielectric material, and chemical-mechanical polishing (CMP) is performed, in accordance with an embodiment of the present invention;

FIG. 10 is a cross-sectional view of the semiconductor structure of FIG. 9 where an interlayer dielectric (ILD) is deposited, CA contacts are formed to source/drain (S/D) epi regions, back-end-of-line (BEOL) processing takes place and a carrier wafer is bonded to the BEOL, in accordance with an embodiment of the present invention;

FIG. 11 is a cross-sectional view of the semiconductor structure of FIG. 10 where the structure is flipped and the substrate is removed to expose the etch stop layer, in accordance with an embodiment of the present invention;

FIG. 12 is a cross-sectional view of the semiconductor structure of FIG. 11 where the etch stop layer and a silicon (Si) layer are removed to expose the BDI layer, as well as the conformal dielectric pillars in the Y1-cut and Y2-cut directions, in accordance with an embodiment of the present invention:

FIG. 13 is a cross-sectional view of the semiconductor structure of FIG. 12 where an ILD is deposited and CA contacts are formed to S/D epi regions, in accordance with an embodiment of the present invention; and

FIG. 14 is a cross-sectional view of the semiconductor structure of FIG. 13 where backside power rails are formed to the backside S/D CA contacts and a backside power delivery network (BSPDN) is connected to the metal contacts, in accordance with an embodiment of the present invention.

Throughout the drawings, same or similar reference numerals represent the same or similar elements.

### DETAILED DESCRIPTION

Embodiments in accordance with the present invention provide methods and devices for constructing backside contacts for cell height scaling. At least one dielectric isolation pillar exists between NFET-to-NFET (N2N) or PFET-to-PFET (P2P) active regions, where the isolation pillar extends from a top surface of a high-k metal gate (HKMG) to a bottom surface of a shallow trench isolation (STI) region, where at least one source/drain (S/D) region next to the dielectric isolation pillar is wired to the frontside back-end-of-line (BEOL) interconnect, and the other S/D region next to the dielectric isolation pillar is wired to the backside power rail (BPR) and backside power distribution network (BSPDN) through a backside contact. This results in a gate extension between an active channel and a gate cut region that is less than a suspension thickness between horizontal channels.

Examples of semiconductor materials that can be used in forming such nanosheet structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

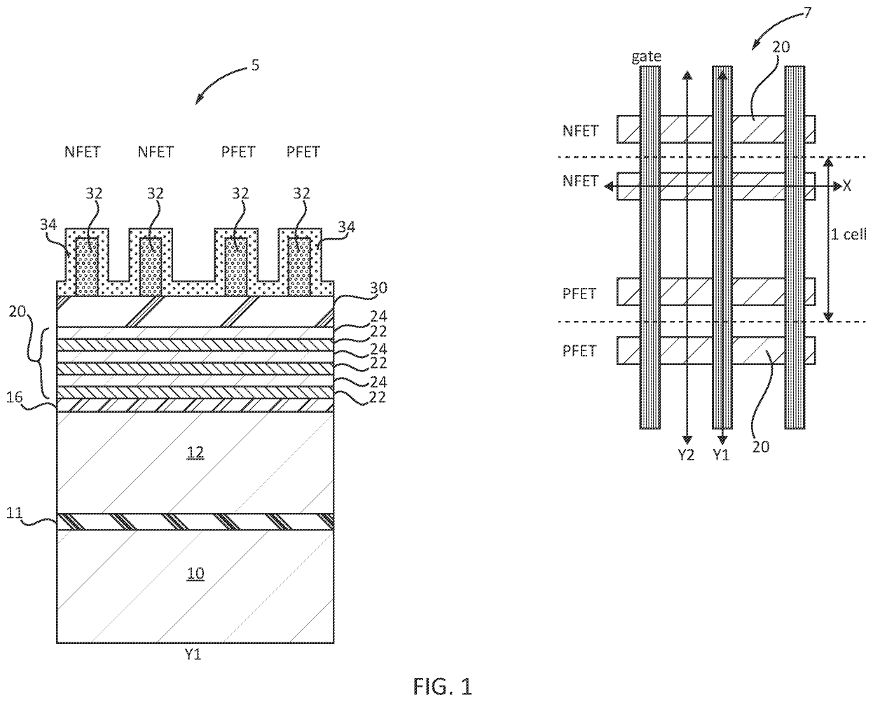

FIG. 1 is a cross-sectional view of a semiconductor structure including a nanosheet stack formed over a substrate, where first and second hardmasks, and a dielectric liner are also formed over the nanosheet stack, in accordance with an embodiment of the present invention.

In various example embodiments, a structure 5 includes a nanosheet stack 20 formed over a substrate 10. An etch stop layer 11 and a silicon (Si) layer 12 can be formed between the substrate 10 and the nanosheet stack 20. The nanosheet stack 20 includes alternating layers of a first semiconductor material (or layer) 22 and a second semiconductor material (or layer) 24. The first semiconductor material 22 can be, e.g., silicon germanium (SiGe) and the second semiconductor material 24 can be, e.g., silicon (Si). Additionally, a SiGe layer 16 with a high concentration of germanium (Ge) is formed directly between the nanosheet stack 20 and the Si layer 12. Then a first hardmask layer 30 and a second hardmask layer are deposited, where the second hardmask layer is patterned to form hardmask fins 32. Finally, a conformal dielectric liner 34 is deposited over the first hardmask layer 30 and the hardmask fins 32.

The top view 7 illustrates the NFETs and PFETs in relation to the gates.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

Referring to, e.g., the nanosheet stack 20, the first semiconductor material 22 can be the first layer in a stack of sheets of alternating materials. The nanosheet stack 20 thus includes first semiconductor materials (or layers) 22 and second semiconductor materials (or layers) 24. Although it is specifically contemplated that the first semiconductor materials 22 can be formed from silicon germanium and that the second semiconductor materials 24 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials 22/24 can be deposited by any appropriate mechanism. It is specifically contemplated that the first and second semiconductor materials 22/24 can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In various embodiments, the hardmask layer 30 and the hardmask fins 32 can be a nitride, for example, a silicon nitride (SiN), an oxynitride, for example, silicon oxynitride (SiON), or a combination thereof.

Regarding various dielectrics or dielectric layers (such as conformal dielectric liner 34) discussed herein, the dielectrics can include, but are not limited to, SiN, SiOCN, SiOC, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

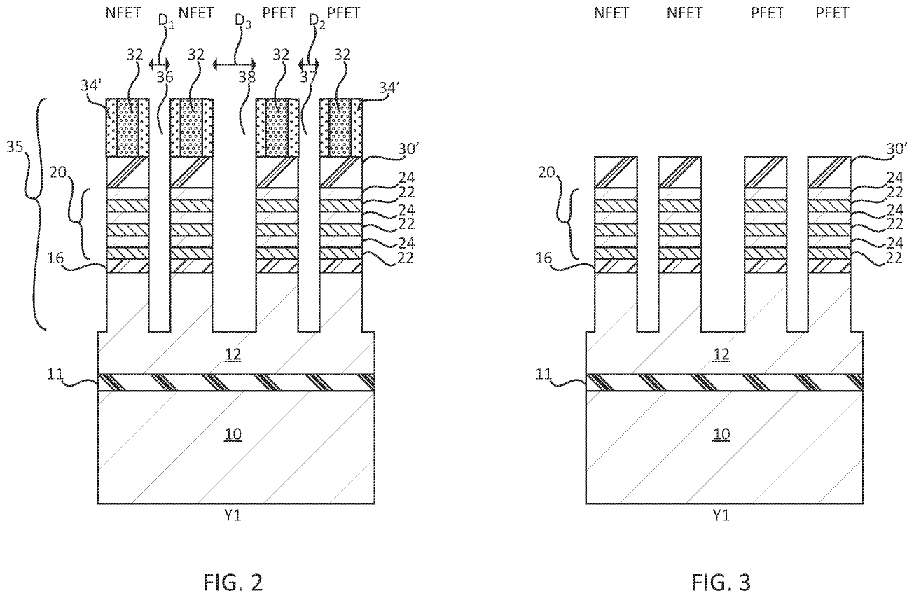

FIG. 2 is a cross-sectional view of the semiconductor structure of FIG. 1 where nanosheet stack patterning takes place, in accordance with an embodiment of the present invention.

In various example embodiments, nanosheet stack patterning takes place such that stacks 35 are formed with remaining first hardmask portions 30′ and conformal dielectric liner portions 34′. An opening 36 between NFETs defines a distance D₁ and an opening 37 between PFETs defines a distance D₂. Distance D₁ can be equal to distance D₂. Distance D₁ and D₂ can be as small as approximately 8 nm. In other words, NFET-to-NFET spacing can be 8 nm and PFET-to-PFET spacing can be 8 nm. An opening 38 is defined as distance D₃ between an NFET and an adjacent PFET, and can be approximately 20 to 50 nm. In other words, NFET-to-PFET spacing can be 20 to 50 nm.

FIG. 3 is a cross-sectional view of the semiconductor structure of FIG. 2 where the second hardmask and remaining dielectric liner portions are selectively removed thus exposing the first hardmask, in accordance with an embodiment of the present invention.

In various example embodiments, the second hardmask or hardmask fins 32 and remaining conformal dielectric liner portions 34′ are selectively removed or etched, thus exposing the remaining first hardmask portions 30′.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

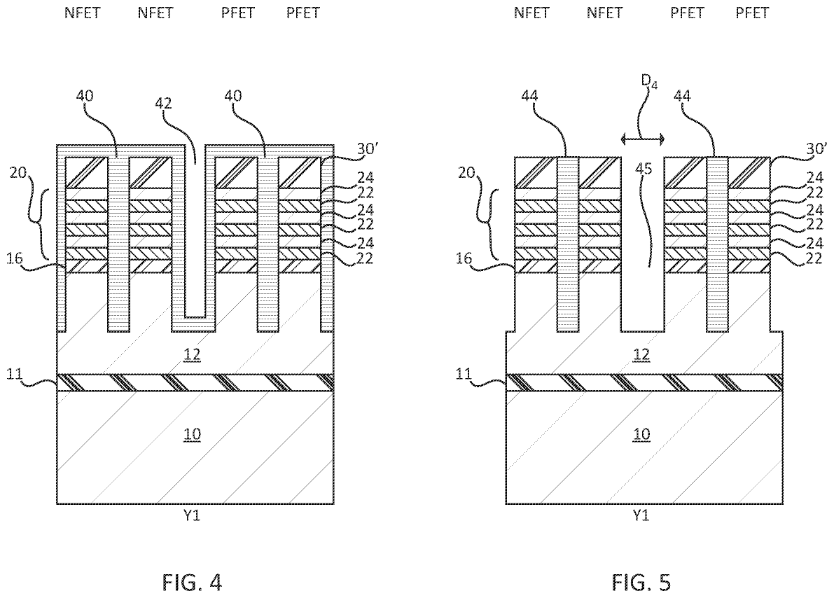

FIG. 4 is a cross-sectional view of the semiconductor structure of FIG. 3 where a first conformal dielectric layer is deposited to pinch-off NFET-to-NFET spacing and PFET-to-PFET spacing, in accordance with an embodiment of the present invention.

In various example embodiments, a first conformal dielectric layer 40 is deposited to pinch-off NFET-to-NFET spacing and PFET-to-PFET spacing. A gap 42 remains between the NFETs and the PFETs.

The first conformal dielectric layer 40 can be any dielectric material as indicated above.

FIG. 5 is a cross-sectional view of the semiconductor structure of FIG. 4 where an isotropic etch back is performed such that conformal dielectric pillars are present between the NFET devices and between the PFET devices, in accordance with an embodiment of the present invention.

In various example embodiments, an isotropic etch back is performed such that conformal dielectric pillars 44 are present between the NFET devices and between the PFET devices. An opening 45 defined by distance D₄ is present between an NFET and an adjacent PFET. A height of the conformal dielectric pillars 44 can be reduced by CMP. The conformal dielectric pillars 44 can also be referred to as dielectric isolation pillars 44. The dielectric isolation pillars 44 are parallel to each other. The dielectric isolation pillars 44 all have a same height and a same width. The dielectric isolation pillars 44 directly contact sidewalls of the nanosheet stacks 20.

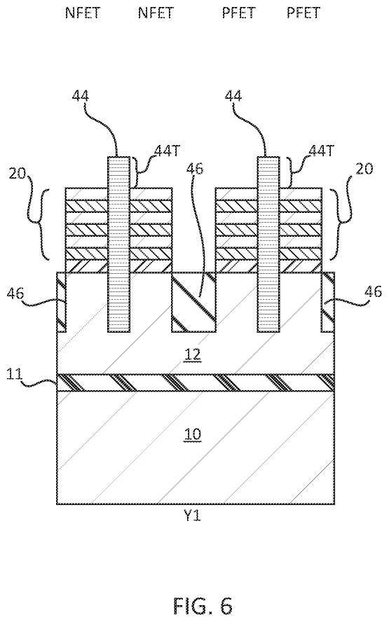

FIG. 6 is a cross-sectional view of the semiconductor structure of FIG. 5 where shallow trench isolation (STI) regions are formed and the first hardmask is selectively removed to expose a top portion of the conformal dielectric pillars, in accordance with an embodiment of the present invention.

In various example embodiments, shallow trench isolation (STI) regions 46 are formed and the remaining first hardmask portions 30′ are selectively removed to expose a top portion 44T of the conformal dielectric pillars 44. The conformal dielectric pillars 44 are formed between and directly contact sidewalls of the nanosheet stacks 20. A bottom surface of the STI regions 46 can be collinear with a bottom surface of the conformal dielectric pillars 44. The conformal dielectric pillars 44 are vertically offset from the STI regions 46.

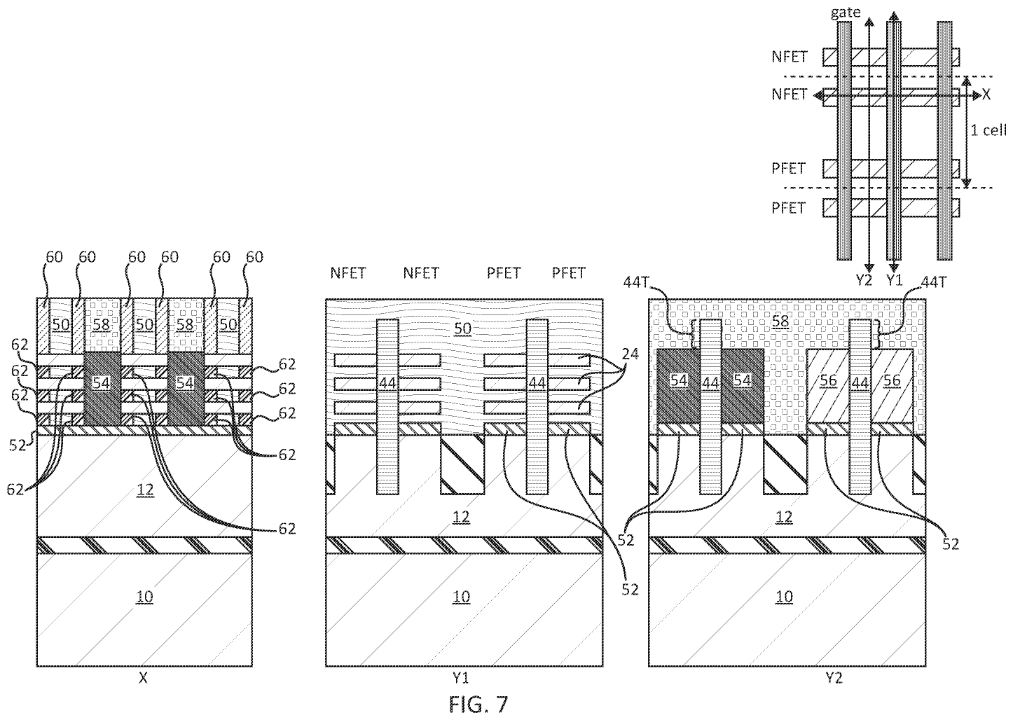

FIG. 7 is a cross-sectional view of the semiconductor structure of FIG. 6 where a silicon germanium (SiGe) layer with a high concentration of germanium (Ge) of the nanosheet stack is removed and replaced with a bottom dielectric isolation (BDI) layer, and where the sacrificial layers of the nanosheet stack are removed and replaced with a high-k metal gate (HKMG), in accordance with an embodiment of the present invention.

In various example embodiments, the SiGe layer 16 with a high concentration of germanium (Ge) is removed and replaced with a bottom dielectric isolation (BDI) layer 52 after dummy gate (not shown) formation. The dummy gates and sacrificial layers of the nanosheet stacks 20 are removed and replaced with a high-k metal gate (HKMG) 50 or replacement metal gates after the S/D epi region 54 and the ILD 58 are formed. Inner spacers 62 are also formed before the S/D epi region 54 formation.

In the X-cut direction, the source/drain (S/D) epi regions 54 are also visible. The S/D epi regions 54 are vertically offset from the HKMG 50. The S/D epi regions 54 directly contact the top surface of the BDI layer 52. An ILD 58 is formed over the S/D epi regions 54. Spacers 60 are formed on opposed ends of the ILDs 58. CMP can be performed to planarize the top surface of the HKMGs 50 and the top surface of the ILDs 58.

In the Y1-cut direction, the source/drain (S/D) epi regions 54 are not visible. In this view, the conformal dielectric pillars 44 are visible. Si layers 24 of the nanosheet stacks are positioned on opposed ends of the conformal dielectric pillars 44 to define a fishbone-like configuration. The BDI layers 52 directly contacts sidewalls of the conformal dielectric pillars 44. The HKMG 50 surrounds the Si layer 24 completely on three sides. The HKMG 50 also directly contacts at least two surfaces of the BDI layers 52. The conformal dielectric pillars 44 extend into the Si layer 12. The HKMG 50 directly contacts sidewalls of the first and second dielectric isolation pillars 44. The first and second dielectric isolation pillars 44 each extend from a top surface of the HKMG 50 to a bottom surface of the STI region 46.

In the Y2-cut direction, the source/drain (S/D) epi regions 54 are visible. For the NFET, a pair of n-type S/D regions 54 are disposed on opposed ends of the conformal dielectric pillar 44. For the PFET, a pair of p-type S/D regions 56 are disposed on opposed ends of the conformal dielectric pillar 44. The dielectric layer 58 directly contacts and surrounds the top portion 44T of the conformal dielectric pillars 44. The dielectric layer 58 also directly contacts the pair of n-type S/D regions 54 and the pair of p-type S/D regions 56. The pair of n-type S/D regions 54 directly contact sidewalls of the conformal dielectric pillar 44 and directly contact a top surface of the BDI layers 52. Similarly, the pair of p-type S/D regions 56 directly contact sidewalls of the conformal dielectric pillar 44 and directly contact a top surface of the BDI layers 52. The conformal dielectric pillars 44 extend into the Si layer 12.

The HKMG material of the replacement metal gates 50 can be deposited by any suitable techniques, such as ALD, CVD, metal-organic CVD (MOCVD), physical vapor deposition (PVD), thermal oxidation, combinations thereof, or other suitable techniques. The gate dielectric material of the replacement metal gates 50 can include, e.g., LaO, AO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfiO, (Ba,Sr)TiO₃(BST), Al₂O₃, Si₃N₄, oxynitrides (SiON), or other suitable materials. The HKMG of the RMG gate 50 further comprises work function metals, such as TiN, TiAl, TiC, TiAlC, etc., and conductive metal fills, such as W, Al, Ru, etc.

The inner spacers 62 can include any of one or more of SiN, SiBN, SiCN and/or SiBCN films.

Source/drain epi regions 54, 56 can be of the same or different materials for pFET and nFET devices, and can be either in-situ doped with appropriate polarity dopants (B for pFET and P for nFET devices) or doped by ion implantation.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The ILD 58 can be any suitable material, such as, for example, porous silicates, carbon doped oxides, silicon dioxides, silicon nitrides, silicon oxynitrides, or other dielectric materials. Any known manner of forming the ILD 58 can be utilized. The ILD 58 can be formed using, for example, CVD, PECVD, ALD, flowable CVD, spin-on dielectrics, or PVD.

The BDI layer 52 can include, e.g., SiC, SiOC, etc. The BDI layer 52 can be deposited by, e.g., ALD with an isotropic etch back.

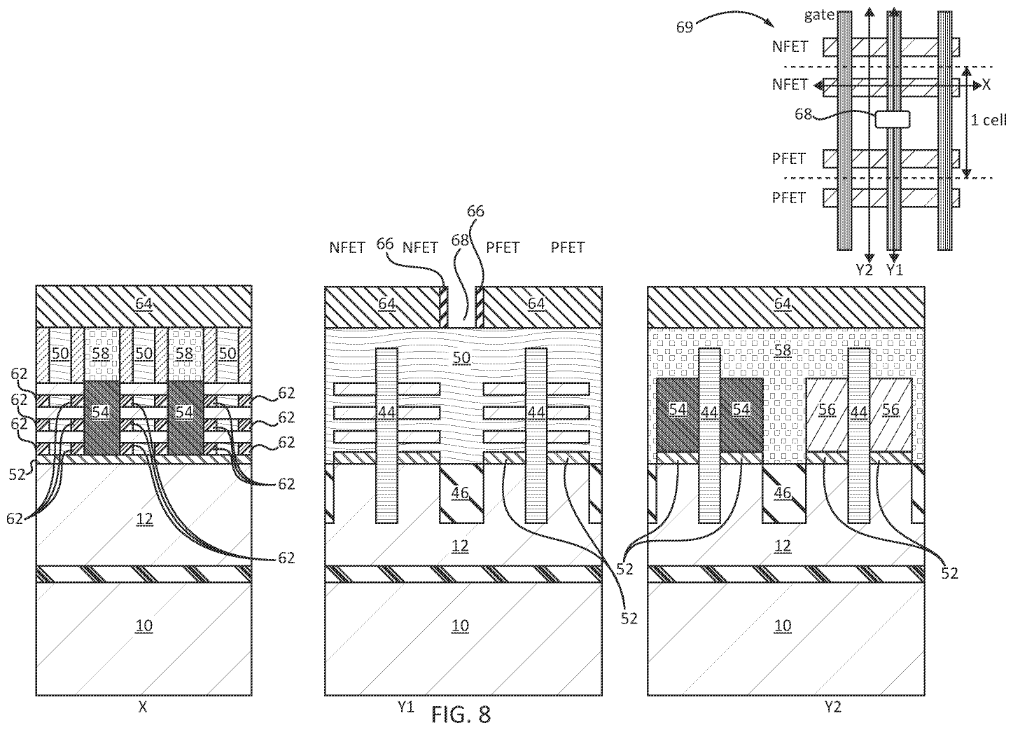

FIG. 8 is a cross-sectional view of the semiconductor structure of FIG. 7 where a hardmask is deposited for gate cut patterning and inner spacers are formed to decrease the critical dimension (CD), in accordance with an embodiment of the present invention.

In various example embodiments, a hardmask 64 is deposited for gate cut patterning and inner spacers 66 are formed to decrease the critical dimension (CD) and create gap 68. The inner spacers 66 are vertically aligned with a portion of the HKMG 50 that is vertically aligned with the STI region 46. The top view 69 illustrates the opening or gap 68 between the NFETs and the PFETs.

In various embodiments, the hardmask 64 can be a nitride, for example, a silicon nitride (SiN), an oxynitride, for example, silicon oxynitride (SiON), or a combination thereof.

The inner spacers 66 can include any of one or more of SiN, SiBN, SiCN and/or SiBCN films.

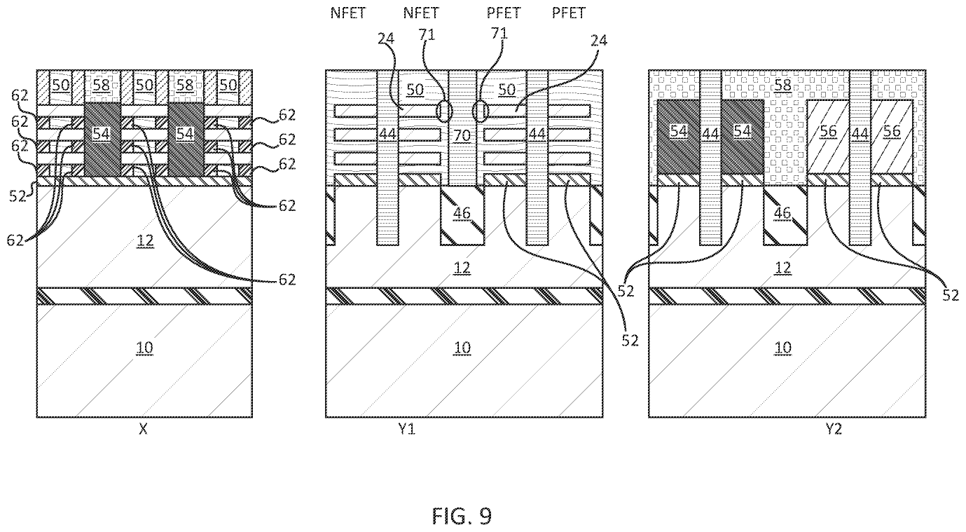

FIG. 9 is a cross-sectional view of the semiconductor structure of FIG. 8 where a gate cut takes place, the gate cut is filled with a dielectric material, and chemical-mechanical polishing (CMP) is performed, in accordance with an embodiment of the present invention.

In various example embodiments, in the Y1-cut direction, a gate cut takes place, the gate cut is filled with a dielectric material 70, and chemical-mechanical polishing (CMP) is performed. The gate cut dimension is smaller because of the inner spacers 66. Thus, region 71 on opposed ends of the dielectric material 70 includes HKMG material 50. In other words, HKMG 50 separates the Si layers 24 from the dielectric material 70. Thus, the inner spacers 66 aid in shrinking the CD to a very small size, such as, e.g., 13 nm. Additionally, the gate extension can be shrunk to a very small size, such as, e.g., 6 nm.

In the Y1-cut direction, the dielectric material 70 extends to and directly contacts a top surface of the STI region 46. The dielectric material 70 defines a dielectric pillar 70 or a dielectric gate cut pillar 70 that is parallel to the conformal dielectric pillars 44. The dielectric gate cut pillar 70 has a length less than a length of the conformal dielectric pillars 44. The dielectric gate cut pillar 70 is vertically offset from the conformal dielectric pillars 44. A width of the dielectric gate cut pillar 70 may be greater than a width of the conformal dielectric pillars 44. The width of the conformal dielectric pillars 44 can be as small as 8 nm. The dielectric gate cut pillar 70 separates the NFETs from the PFETs, whereas the conformal dielectric pillars 44 separate the NFETs from each other and the PFETs from each other. In other words, the dielectric gate cut pillar 70 separates the pair of pFETs from the pair of nFETs, the dielectric gate cut pillar 70 is vertically aligned with an STI region 46 and the dielectric gate cut pillar 70 is parallel to both the first and second dielectric isolation pillars 44.

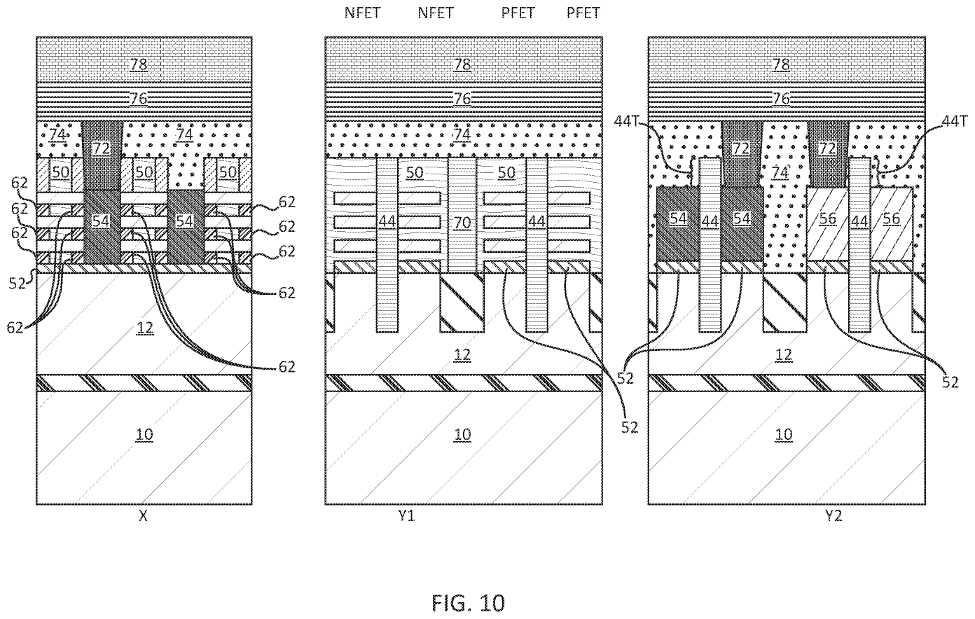

FIG. 10 is a cross-sectional view of the semiconductor structure of FIG. 9 where an interlayer dielectric (ILD) is deposited, CA contacts are formed to source/drain (S/D) epi regions, back-end-of-line (BEOL) processing takes place and a carrier wafer is bonded to the BEOL, in accordance with an embodiment of the present invention.

In various example embodiments, an interlayer dielectric (ILD) 74 is deposited, CA contacts 72 are formed to S/D epi regions 54, 56, back-end-of-line (BEOL) processing 76 takes place and a carrier wafer 78 is bonded to the BEOL 76.

In the X-cut direction, the CA contact 72 directly contacts the n-type S/D epi region 54. The CA contact 72 is vertically offset from any HKMG 50.

In the Y2-cut direction, one CA contact 72 directly contacts the n-type S/D epi region 54 and another CA contact 72 directly contacts the p-type S/D epi region 56. The CA contacts 72 are vertically offset from the conformal dielectric pillars 44. The top portion 44T of the conformal dielectric pillars 44 extend adjacent the lower portions of the CA contacts 72. However, the CA contacts do not directly contact the conformal dielectric pillars 44.

Non-limiting examples of suitable conductive materials for the CA contacts 72 include a silicide liner such as Ti, Ni, NiPt, etc., an adhesion metal liner, such as TiN, TaN, and conductive metal fill, such as Al, W, Co, Ru, etc. The conductive material can further include dopants that are incorporated during or after deposition. The conductive metal can be deposited by a suitable deposition process, for example, CVD, PECVD, PVD, plating, thermal or e-beam evaporation, and sputtering.

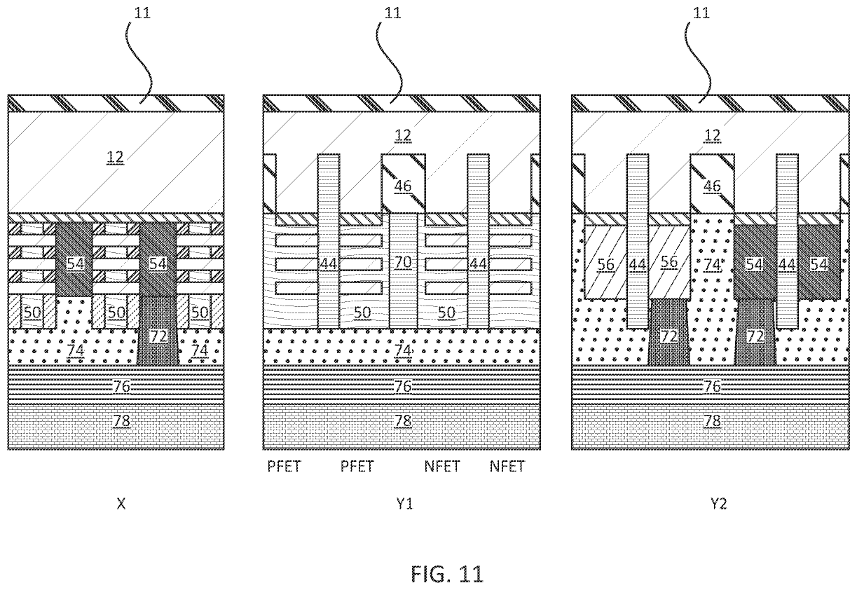

FIG. 11 is a cross-sectional view of the semiconductor structure of FIG. 10 where the structure is flipped and the substrate is removed to expose the etch stop layer, in accordance with an embodiment of the present invention.

In various example embodiments, the structure is flipped and the substrate 10 is removed to expose the etch stop layer 11.

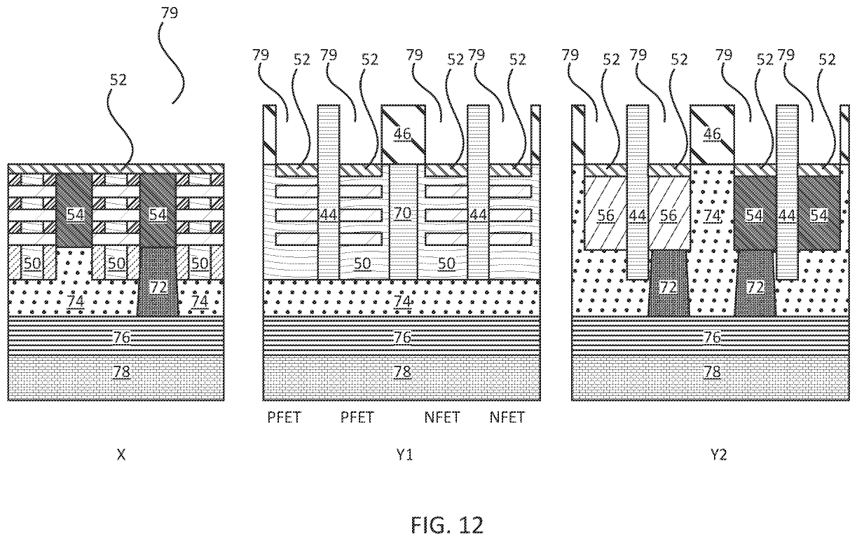

FIG. 12 is a cross-sectional view of the semiconductor structure of FIG. 11 where the etch stop layer and a silicon (Si) layer are removed to expose the BDI layer, as well as the conformal dielectric pillars in the Y1-cut and Y2-cut directions, in accordance with an embodiment of the present invention.

In various example embodiments, the etch stop layer 11 and the Si layer 12 are removed to expose the BDI layer 52, as well as the conformal dielectric pillars 44 in the Y1-cut and Y2-cut directions. Openings 79 are formed.

In the X-cut direction, the BDI layer 52 is fully visible.

In the Y1-cut direction, a larger top portion of the conformal dielectric pillars 44 is exposed. The STI region 46 remains present and prevents the exposure of the dielectric gate cut pillar 70. The BDI layers 52 are also visible.

In the Y2-cut direction, a larger top portion of the conformal dielectric pillars 44 is exposed. Additionally, the BDI layers 52 are also visible.

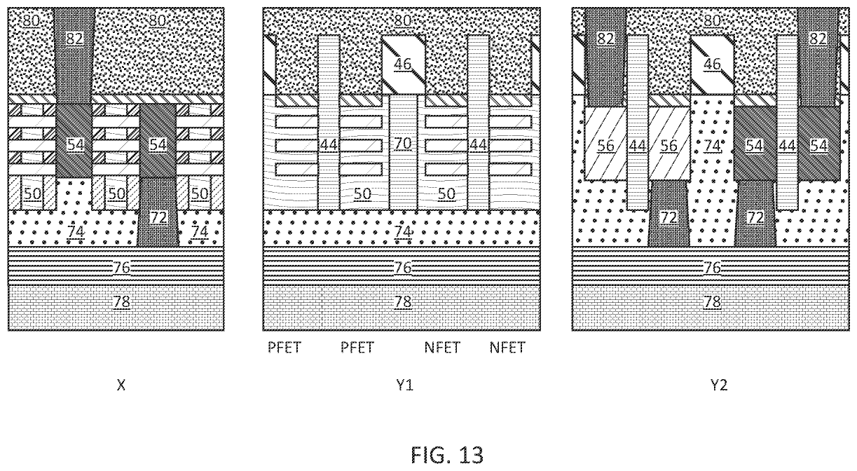

FIG. 13 is a cross-sectional view of the semiconductor structure of FIG. 12 where an ILD is deposited and a backside S/D CA contacts are formed to source/drain (S/D) epi regions, in accordance with an embodiment of the present invention.

In various example embodiments, an ILD 80 is deposited and the backside S/D CA contacts 82 are formed to S/D epi regions 54, 56. The ILD 80 completely covers the conformal dielectric pillars 44 in the Y1-cut and Y2-cut directions. The ILD 80 directly contacts the top surfaces of the BDI layers 52. The first contact 72 is horizontally and vertically offset from the second contact 82. The BDI layer 52 directly contacts a top surface of the first and second S/D epi regions 54, 56 and the BDI layer 52 directly contacts sidewalls of the first and second dielectric isolation pillars 44.

The ILD 80 can be any suitable material, such as, for example, porous silicates, carbon doped oxides, silicon dioxides, silicon nitrides, silicon oxynitrides, or other dielectric materials. Any known manner of forming the ILD 80 can be utilized. The ILD 80 can be formed using, for example, CVD, PECVD, ALD, flowable CVD, spin-on dielectrics, or PVD.

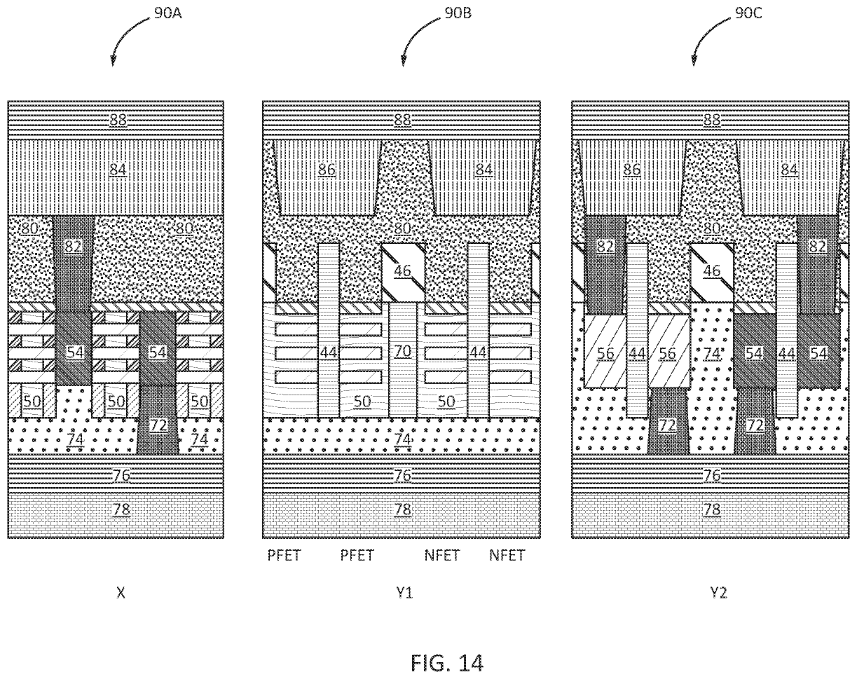

FIG. 14 is a cross-sectional view of the semiconductor structure of FIG. 13 where backside power rails are formed to the backside S/D CA contacts and a backside power delivery network (BSPDN) is connected to the metal contacts, in accordance with an embodiment of the present invention.

In various example embodiments, backside power rails 84, 86 are formed to the CA contacts 82 and a backside power delivery network (BSPDN) 88 is connected to the metal contacts 84, 86 to form structures 90A (X-cut), 90B (Y1-cut), and 90C (Y2-cut). The ILD 80 can separate metal contact 84 (VSS) from metal contact 86 (VDD).

Therefore, the semiconductor structures 90A, 90B, 90C include a first dielectric isolation pillar 44 disposed between a pair of p-type field effect transistors (pFETs), a second dielectric isolation pillar 44 disposed between a pair of n-type FETs (nFETs), a first source/drain (S/D) epi region having a first contact 82 electrically connected to a backside power delivery network (BSPDN) 88, the first contact 82 disposed on one side of the first dielectric isolation pillar 44, and a second S/D epi region having a second contact 72 electrically connected to back-end-of-line (BEOL) components 76, the second contact 82 disposed on the other side of the first dielectric isolation pillar 44. The first contact 72 extends along a first sidewall of the dielectric isolation pillar 44 and a second contact 82 extends along a second sidewall of the dielectric isolation pillar 44, where the first and second sidewalls are in opposed relation to each other.

In conclusion, the exemplary embodiments of the present invention present a backside contact where cell height scaling is achieved. The exemplary embodiments of the present invention provide methods and devices for constructing backside contacts for cell height scaling where at least a dielectric isolation pillar exists between NFET-to-NFET (N₂N) or PFET-to-PFET (P2P) active regions, where the isolation pillar extends from a top surface of a HKMG to a bottom surface of an STI region, where at least one S/D region next to the dielectric isolation pillar is wired to the frontside BEOL interconnect, and the other S/D region next to the dielectric isolation pillar is wired to the backside power rail (BPR) and backside power distribution network (BSPDN) through a backside contact. This results in a gate extension between an active channel and a gate cut region that is less than a suspension thickness between horizontal channels.

Regarding FIGS. 1-14, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing backside contacts for ultimate cell height scaling (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a first dielectric isolation pillar disposed between a pair of p-type field effect transistors (pFETs);
a second dielectric isolation pillar disposed between a pair of n-type FETs (nFETs);
a first source/drain (S/D) epi region having a first contact electrically connected to a backside power delivery network (BSPDN), the first contact being disposed on one side of the first dielectric isolation pillar; and
a second S/D epi region having a second contact electrically connected to back-end-of-line (BEOL) components, the second contact being disposed on the other side of the first dielectric isolation pillar.

2. The semiconductor structure of claim 1, wherein a high-k metal gate (HKMG) directly contacts sidewalls of the first and second dielectric isolation pillars.

3. The semiconductor structure of claim 2, wherein the first and second dielectric isolation pillars each extend from a top surface of the HKMG to a bottom surface of a shallow trench isolation (STI) region.

4. The semiconductor structure of claim 1, wherein a dielectric gate cut pillar separates the pair of pFETs from the pair of nFETs.

5. The semiconductor structure of claim 4, wherein the dielectric gate cut pillar is vertically aligned with an STI region.

6. The semiconductor structure of claim 4, wherein the dielectric gate cut pillar is parallel to both the first and second dielectric isolation pillars.

7. The semiconductor structure of claim 1, wherein the first contact is horizontally and vertically offset from the second contact.

8. The semiconductor structure of claim 1, wherein a bottom dielectric isolation (BDI) layer directly contacts a top surface of the first and second S/D epi regions.

9. The semiconductor structure of claim 1, wherein a bottom dielectric isolation (BDI) layer directly contacts sidewalls of the first and second dielectric isolation pillars.

10. A semiconductor structure comprising:
at least one dielectric isolation pillar disposed between a pair of field effect transistors (FETs);
a first source/drain (S/D) epi region having a first contact electrically connected to a backside power delivery network (BSPDN), the first contact being disposed along a first sidewall of the at least one dielectric isolation pillar; and
a second S/D epi region having a second contact electrically connected to back-end-of-line (BEOL) components, the second contact being disposed along a second sidewall of the at least one dielectric isolation pillar, wherein the first sidewall is in opposed relation to the second sidewall.

11. The semiconductor structure of claim 10, wherein a high-k metal gate (HKMG) directly contacts sidewalls of the at least one dielectric isolation pillar.

12. The semiconductor structure of claim 11, wherein the at least one dielectric isolation pillar extends from a top surface of the HKMG to a bottom surface of a shallow trench isolation (STI) region.

13. The semiconductor structure of claim 10, wherein a dielectric gate cut pillar is vertically aligned with an STI region.

14. The semiconductor structure of claim 13, wherein the dielectric gate cut pillar is parallel to the at least one dielectric isolation pillar.

15. The semiconductor structure of claim 10, wherein the first contact is horizontally and vertically offset from the second contact.

16. The semiconductor structure of claim 10, wherein a bottom dielectric isolation (BDI) layer directly contacts a top surface of the first and second S/D epi regions.

17. A method comprising:
constructing a first dielectric isolation pillar between a pair of p-type field effect transistors (pFETs);
constructing a second dielectric isolation pillar between a pair of n-type FETs (nFETs);
forming a first source/drain (S/D) epi region having a first contact and electrically connected to a backside power delivery network (BSPDN), the first contact being disposed on one side of the first dielectric isolation pillar; and
forming a second S/D epi region having a second contact and electrically connected to back-end-of-line (BEOL) components, the second contact being disposed on the other side of the first dielectric isolation pillar.

18. The method of claim 17, wherein a dielectric gate cut pillar separates the pair of pFETs from the pair of nFETs.

19. The method of claim 18,
wherein the dielectric gate cut pillar is vertically aligned with an STI region; and
wherein the dielectric gate cut pillar is parallel to both the first and second dielectric isolation pillars.

20. The method of claim 17, wherein a bottom dielectric isolation (BDI) layer directly contacts a top surface of the first and second S/D epi regions.
